(19) United States
(12) Patent Application Publication
(10) Pub. No.: US 2026/0202762 A1
(43) Pub. Date: Jul. 16, 2026

(54) EXPOSURE APPARATUS, EXPOSURE METHOD AND ARTICLE MANUFACTURING METHOD

(71) Applicant: CANON KABUSHIKI KAISHA, Tokyo (JP)

(72) Inventors: HIRONOBU FUJISHIMA, Saitama (JP); KAZUHIKO MISHIMA, Tochigi (JP); TSUTOMU TAKENAKA, Tochigi (JP)

(21) Appl. No.: 19/421,335

(22) Filed: Dec. 16, 2025

(30) Foreign Application Priority Data
Jan. 14, 2025 (JP) 2025-004945

(51) Int. Cl. G03F 7/00

(52) U.S. Cl. CPC G03F 7/70775; G03F 7/70725; G03F 7/7085

(57) ABSTRACT

An exposure apparatus including a first mark having a longitudinal direction in a first direction, and a second mark having a longitudinal direction in a second direction different from the first direction, the first mark and the second mark being arranged on a surface on which an original is arranged, a third mark having a longitudinal direction in the first direction, and a fourth mark having a longitudinal direction in the second direction, the third mark and the fourth mark being arranged on a substrate stage configured to hold a substrate, and a detector configured to detect a first light amount of light having passed through the first mark and the third mark, and a second light amount of light having passed through the second mark and the fourth mark, thereby obtaining light amount information.

### BACKGROUND

### Field of the Technology

The present disclosure relates to an exposure apparatus, an exposure method and an article manufacturing method.

### Description of the Related Art

In the manufacturing process of a semiconductor element formed from a micropattern, an exposure apparatus is used to reduce a pattern rendered on an original (reticle or mask), and project and transfer it to a photosensitive material (photoresist)-applied substrate (wafer). To meet a request for higher resolutions, the exposure apparatus needs to improve the consistency (overlay accuracy) between the pattern of a reticle and that of a substrate. The exposure apparatus also needs to increase the productivity (throughput) while satisfying these requests.

To improve the overlay accuracy, it is necessary to align an original and substrate at high accuracy. As a method of aligning an original and a substrate, there is known a method of arranging, on both the original side and the substrate side, a mark formed from an opening (transmitting portion) that transmits light, and a light-shielding portion that shields light. When the original-side mark is illuminated, light having passed through the opening forms the image of the original-side mark on a reference mark (substrate-side mark) provided on a substrate stage that holds a substrate. When (the opening of) the reference mark is relatively changed in the horizontal direction and the focus direction with respect to the image of the original-side mark, the intensity of light having passed through the reference mark changes. From information about the change, the relative positions of the original and substrate stage (substrate) can be obtained.

The exposure apparatus needs to maximize the performance from the viewpoint of the throughput, so the time taken to obtain the relative positions of an original and substrate needs to be shortened as much as possible. Even for only one portion, the relative displacement between the original and the substrate exists in two horizontal directions and one focus direction, that is, a total of three directions. In addition, measurement is necessary at a plurality of image heights to grasp the magnification component of a projection optical system, the rotational component of the original, and the like, and align the effective patterning region of the original to a predetermined position of the substrate. To obtain the relative positions of the original and substrate, multiple multiaxial driving is inevitable for the substrate stage. Further, every time the driving mode is switched, an acceleration/deceleration operation is generated.

To minimize the influence on throughput, Japanese Patent Laid-Open No. 2008-53618 and Japanese Patent No. 5457767 have proposed techniques regarding mark arrangement and a measurement sequence for completing measurement efficiently and by simple stage driving. For example, Japanese Patent Laid-Open No. 2008-53618 has disclosed a technique of parallelly processing marks arranged at a plurality of image heights. More specifically, paired X- and Y-direction measurement marks are arranged at left and right ends of an original, and the two left and right image heights are simultaneously measured so that the relative positions of the original and substrate can be obtained within a short time. According to this technique, the X- and Y-direction measurement marks corresponding to the two, left and right image heights are arranged as reference marks that are substrate-side marks. Japanese Patent No. 5457767 has disclosed a technique regarding preprocessing of correcting the imaging magnification and distortion of a projection optical system and the like before measuring the relative positions of an original and substrate.

However, even the technique disclosed in Japanese Patent Laid-Open No. 2008-53618 requires two-time measurement in the X and Y directions for each of the horizontal direction and the focus direction. If the distance between left and right image heights on the substrate side is different from a design value owing to the magnification error and distortion of the projection optical system and the like, or changes over time, it cannot be expected that the original-side mark and the substrate-side mark completely overlay each other (have a conjugate imaging relationship). As a result, the contrast of an intensity change along the movement of the substrate stage decreases, and a decrease in measurement accuracy (reliability) is inevitable.

To the contrary, the technique disclosed in Japanese Patent No. 5457767 ca stabilize the measurement accuracy, but further adds preprocessing in a situation in which two measurements are necessary in the X and Y directions for each of the horizontal direction and the focus direction. This contradicts the request for higher throughput of the exposure apparatus.

### SUMMARY

The present disclosure provides a technique advantageous for aligning an original and a substrate.

According to one aspect of the present disclosure, there is provided an exposure apparatus that projects a pattern of an original onto a substrate via a projection optical system, and exposes the substrate, the apparatus including a first mark having a longitudinal direction in a first direction, and a second mark having a longitudinal direction in a second direction different from the first direction, the first mark and the second mark being arranged on a surface on which the original is arranged, a third mark having a longitudinal direction in the first direction, and a fourth mark having a longitudinal direction in the second direction, the third mark and the fourth mark being arranged on a substrate stage configured to hold the substrate, a detector configured to detect a first light amount of light having passed through the first mark and the third mark, and a second light amount of light having passed through the second mark and the fourth mark, thereby obtaining light amount information, and a controller configured to obtain pieces of light amount information respectively about the first light amount and the second light amount by the detector by moving, in a third direction obliquely crossing the first direction and the second direction, the substrate stage along a surface holding the substrate to include a state in which an image of the first mark overlaps the third mark, and a state in which an image of the second mark overlaps the fourth mark, and obtain, based on the pieces of light amount information, relative positions of the first mark and the third mark, and relative positions of the second mark and the fourth mark.

Further aspects of the present disclosure will become apparent from the following description of exemplary embodiments with reference to the attached drawings.

### BRIEF DESCRIPTION OF THE DRAWINGS

FIG. 1 is a schematic view illustrating configurations of an exposure apparatus according to an aspect of the present disclosure.

FIG. 2 is a view illustrating the configurations of a substrate-side reference plate.

FIG. 3 is a view for explaining alignment processing between an original and a substrate in a conventional technique.

FIG. 4 is a view for explaining alignment processing between the original and the substrate in the conventional technique.

FIG. 5 is a view for explaining alignment processing between an original and a substrate in a comparative example.

FIG. 6 is a view for explaining alignment processing between an original and a substrate in an embodiment.

FIG. 7 is a view for explaining alignment processing between the original and the substrate in the embodiment.

FIG. 8 is a view for explaining alignment processing between the original and the substrate in the embodiment.

FIG. 9 is a view for explaining alignment processing between an original and a substrate in a comparative example.

FIG. 10 is a graph illustrating an example of waveforms each representing the amount of light detected by a second original measurement system.

### DESCRIPTION OF THE EMBODIMENTS

Embodiments will be described in detail below with reference to the accompanying drawings. Note that the following embodiments do not limit the claims. A plurality of features are described in the embodiments, but not all the features are essential, and a plurality of features may be arbitrarily combined. In the accompanying drawings, the same reference numerals denote the same or similar parts and a repetitive description thereof will be omitted.

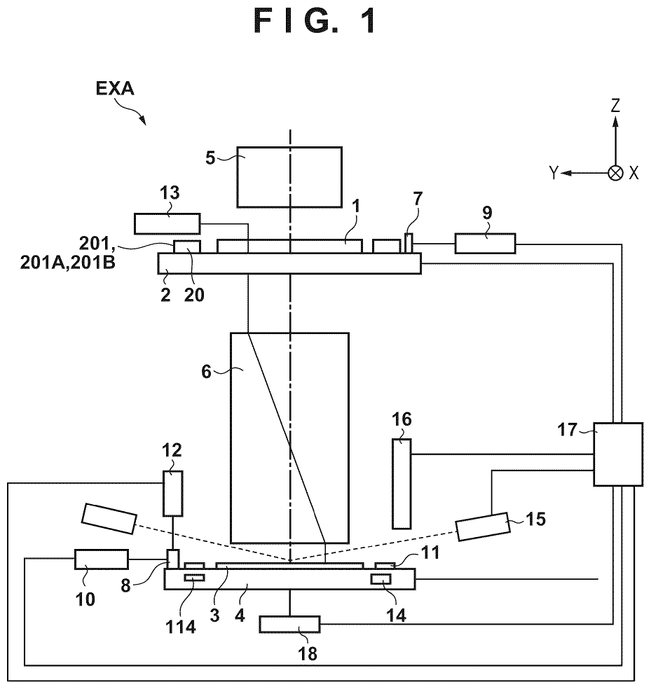

FIG. 1 is a schematic view illustrating configurations of an exposure apparatus EXA according to an aspect of the present disclosure. The exposure apparatus EXA is a lithography apparatus that is used for the manufacturing process of a device such as a semiconductor element, and exposes a substrate via an original (reticle or mask) to form a pattern on the substrate. The exposure apparatus EXA projects the pattern of an original onto a substrate via a projection optical system, and transfers it to the substrate.

The exposure apparatus EXA includes an original stage 2 that holds an original 1, a substrate stage 4 that holds a substrate 3, and an illumination optical system 5 that illuminates the original 1 held by the original stage 2. The exposure apparatus EXA also includes a projection optical system 6 that projects, onto the substrate 3 held by the substrate stage 4, the pattern (image) of the original 1 illuminated by the illumination optical system 5, and a controller 17 that comprehensively controls the overall operation of the exposure apparatus EXA.

In this embodiment, the exposure apparatus EXA is implemented as a scanning exposure apparatus (scanner) that transfers the pattern of the original 1 to the substrate 3 while synchronously scanning the original 1 and the substrate 3 in the scanning direction (that is, by a step-and-scan method). Note that the exposure apparatus EXA may be implemented as an exposure apparatus (stepper) that fixes the original 1 (that is, by a step-and-repeat method), and transfers the pattern of the original 1 to the substrate 3.

In this specification and the accompanying drawings, directions are represented in an XYZ coordinate system in which a direction parallel to a surface on which the substrate 3 is arranged is defined as an X-Y plane. Directions respectively parallel to the X-axis, the Y-axis, and the Z-axis in the XYZ coordinate system will be defined as the X direction, the Y direction, and the Z direction. A rotation about the X-axis, a rotation about the Y-axis, and a rotation about the Z-axis will be defined as θX, θY, and θZ, respectively. The Z direction is a direction coincident with the optical axis of the projection optical system 6, the Y direction is a scanning direction in which the original 1 and the substrate 3 are scanned, and the X direction is a non-scanning direction.

The illumination optical system 5 illuminates (a predetermined illumination region of) the original 1 with light of a uniform illuminance distribution. Light illuminating the original 1, that is, exposure light includes, for example, an i-line generated from a mercury lamp, and a short-wavelength ultraviolet ray from a KrF excimer laser or an ArF excimer laser. Exposure light also includes an extreme ultraviolet ray (EUV ray) having a wavelength of several nm to several hundred nm at which a finer semiconductor element or the like can be manufactured.

The original stage 2 is a movable stage for holding and positioning the original 1 and an original-side reference plate 20. The original stage 2 is constituted to be movable two-dimensionally within a plane perpendicular to the optical axis of the projection optical system 6, that is, the X-Y plane via a driving mechanism including a linear motor and the like, and be rotatable in the θZ direction.

A mirror 7 is provided on the original stage 2. At a position opposite t the mirror 7, a laser interferometer 9 is provided to measure the position of the original stage 2 via the mirror 7. Positions of (the original 1 and original-side reference plate 20 held by) the original stage 2 in the two-dimensional directions and the rotational direction are measured in real time by the laser interferometer 9, and the measurement result is output to the controller 17. The controller 17 moves the original stage 2 via the driving mechanism based on the measurement result of the laser interferometer 9, thereby positioning the original 1 and original-side reference plate 20 that are held by the original stage 2.

The original-side reference plate 20 is an alternate member of the original that is so provided that calibration of the exposure apparatus EXA can be executed even in a state in which the original 1 is not held by the original stage 2. The original-side reference plate 20 includes at least one reference mark 201. The reference mark 201 is a mark detected by a second original measurement system 14. The reference mark 201 includes a first mark 201A whose longitudinal direction is the first direction (Y direction), and a second mark 201B whose longitudinal direction is the second direction (X direction) different from the first direction (perpendicular to the first direction). The first mark 201A is typically formed from a plurality of mark groups in which openings (transmitting portions) that transmit light, and light-shielding portions that shield light are periodically arrayed in the second direction. The second mark 201B is typically formed from a plurality of mark groups in which openings (transmitting portions) that transmit light, and light-shielding portions that shield light are periodically arrayed in the first direction. In the reference mark 201 (first mark 201A and second mark 201B), the ratio between the width of the opening and that of the light-shielding portion is, for example, 1:3. Note that the reference mark 201 may be provided not on the original-side reference plate 20, but on the original 1. In other words, the reference mark 201 suffices to be arranged on a surface (position) on which the original 1 is arranged, that is, the object plane of the projection optical system 6.

The projection optical system 6 is an optical system that includes a plurality of optical elements, and projects the pattern of the original 1 or the reference mark 201 of the original-side reference plate 20 onto the substrate 3 at a predetermined projection magnification. In this embodiment, the projection optical system 6 is a reduction projection system having a projection magnification of less than 1.

The substrate stage 4 is a movable stage for holding and positioning the substrate 3. The substrate stage 4 includes a θZ tilt stage that holds the substrate 3 via a chuck, an X-Y stage that supports the θZ tilt stage, and a base that supports the X-Y stage. The substrate stage 4 is constituted to be movable via a driving mechanism 18 including a linear motor and the like.

A target 8 including a mirror or a grating is provided on the substrate stag 4. At a position opposite to the target 8, measurement units 10 and 12 each including a laser interferometer or an encoder head is provided to measure the position of the substrate stage 4 via the target 8. Positions of (the substrate 3 held by) the substrate stage 4 in the X direction, the Y direction, and the θZ direction are measured in real time by the measurement unit 10, and the measurement result is output to the controller 17. In addition, positions of the substrate stage 4 in the Z direction, the θX direction, and the θY direction are measured in real time by the measurement unit 12, and the measurement result is output to the controller 17. The controller 17 moves the substrate stage 4 via the driving mechanism 18 based on the measurement results of the measurement units 10 and 12, thereby positioning the substrate 3 held by the substrate stage 4.

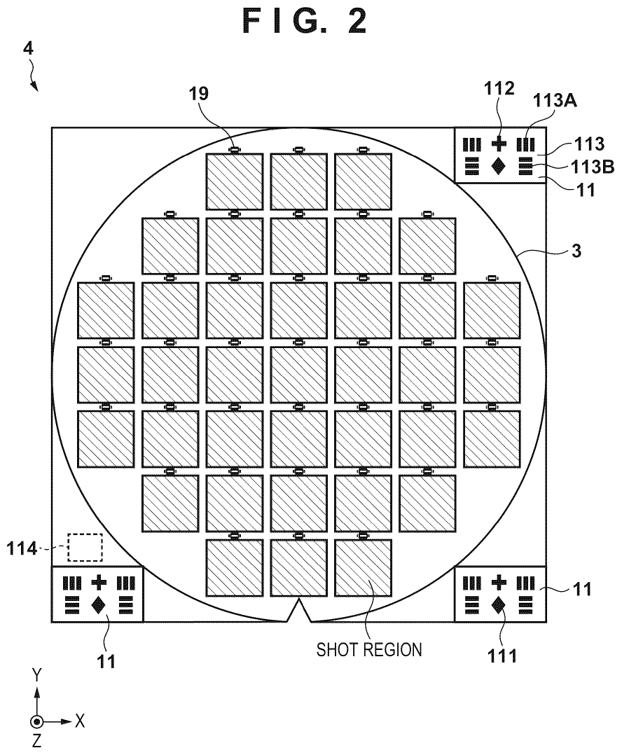

A substrate-side reference plate 11 is provided on at least one corner of the substrate stage 4. The substrate-side reference plate 11 is provided on the substrate stage 4 at the same level as the surface of the substrate 3. FIG. 2 is a view illustrating the configurations of the substrate-side reference plate 11 provided on the substrate stage 4.

The substrate-side reference plate 11 includes a reference mark 111 detected by a first original measurement system 13, a reference mark 112 detected by a substrate measurement system 16, and a reference mark 113 detected by a second original measurement system 14. Several reference marks 111, 112, or 113 may be provided on the substrate-side reference plate 11, or may constitute a mark group formed from several marks. The reference mark 113 includes a third mark 113A whose longitudinal direction is the first direction (Y direction), and a fourth mark 113B whose longitudinal direction is the second direction (X direction) different from the first direction (perpendicular to the first direction). The third mark 113A is typically formed from a plurality of mark groups in which openings (transmitting portions) that transmit light, and light-shielding portions that shield light are periodically arrayed in the second direction. The fourth mark 113B is typically formed from a plurality of mark groups in which openings (transmitting portions) that transmit light, and light-shielding portions that shield light are periodically arrayed in the first direction. In the reference mark 113 (third mark 113A and fourth mark 113B), the pitch between the opening and the light-shielding portion is the same as that of the reference mark 201, but the ratio between the width of the opening and that of the light-shielding portion is, for example, 1:4. In this embodiment, assume that the positional relationship (X and Y directions) between the reference mark 111 or the reference mark 113 and the reference mark 112 is known.

In the exposure apparatus EXA, when the measurement units 10 and 12 measure the position of the substrate stage 4 via the target 8, a higher measurement accuracy can be implemented at a shorter distance by which measurement light from the measurement units 10 and 12 propagates through air from the viewpoint of fluctuations of the refraction index of air. Thus, to measure the reference marks 111, 112, and 113 provided on the substrate-side reference plate 11 at high accuracy, the lower left substrate-side reference plate 11 illustrated in FIG. 2 is preferably used.

A thermometer 114 is provided near the substrate-side reference plate 11. In this embodiment, the thermometer 114 is provided on the substrate stage 4 to measure the ambient temperature of the substrate stage 4.

The first original measurement system 13 is provided near the original stage 2. The first original measurement system 13 irradiates an original-side reference mark (not shown) with light from the same light source as a light source that emits exposure light to expose the substrate 3. The first original measurement system 13 also irradiates the substrate-side reference mark 111 via the projection optical system 6. The first original measurement system 13 includes a photoelectric conversion element (for example, a CCD camera) that accumulates (detects) light (reflected light) from an original-side reference mark and the substrate-side reference mark 111 and photoelectrically converts the light. Based on a signal from the photoelectric conversion element, the first original measurement system 13 measures the positions of these reference marks. The position of the reference mark measured by the first original measurement system 13 is used to align the original 1 and the substrate 3. For example, the relative positions (X, Y, and Z directions) of the original 1 and substrate 3 can be aligned by aligning the positions and focuses of the original-side reference mark and substrate-side reference mark 111.

In addition to the first original measurement system 13, at least one second original measurement system 14 is provided below the substrate-side reference plate 11. The second original measurement system 14 is a transmissive measurement system that includes a detector formed from a light amount sensor or an image sensor, and detects light having passed through the reference mark 113 (openings of the third mark 113A and fourth mark 113B) of the substrate-side reference plate 11. The second original measurement system 14 irradiates the original-side reference mark 201 with light from the same light source as a light source that emits exposure light to expose the substrate 3. The second original measurement system 14 also irradiates the substrate-side reference mark 113 via the projection optical system 6. The light having passed through the original-side reference mark 201 forms an image on the substrate-side reference plate 11 via the projection optical system 6, and the light having passed through the substrate-side reference mark 113 is detected by the second original measurement system 14. At this time, the substrate stage 4 is moved in the X, Y, and Z directions. Based on information obtained from a change of the amount of light having passed through the substrate-side reference mark 113, the positions and focuses of the original-side reference plate 20 (or the original 1) and substrate-side reference plate 11 can be aligned.

In this manner, in the exposure apparatus EXA, the relative positions of the original stage 2 (original 1) and substrate stage 4 (substrate 3) can be aligned using either of the first original measurement system 13 and the second original measurement system 14. In this embodiment, alignment using the second original measurement system 14, which is a transmissive original measurement system, will be mainly explained below.

A focus measurement system 15 includes an irradiation system that irradiates the substrate 3 held by the substrate stage 4 with obliquely incident light, and a detection system that detects light reflected by the substrate 3. The focus measurement system 15 measures a focus, and outputs the measurement result to the controller 17. The controller 17 controls a position (focus position) of the substrate 3 held by the substrate stage 4 in the Z direction and its inclination angle by moving the substrate stage 4 in the Z direction via the driving mechanism 18 based on the measurement result of the focus measurement system 15.

The substrate measurement system 16 includes an irradiation system that irradiates with light an alignment mark 19 of the substrate 3 and the reference mark 112 of the substrate-side reference plate 11, and a detection system that detects light reflected by the alignment mark 19 or the reference mark 112. The substrate measurement system 16 measures the position of the alignment mark 19 or reference mark 112, and outputs the measurement result to the controller 17. The controller 17 controls positions of the substrate 3 held by the substrate stage 4 in the X and Y directions by moving the substrate stage 4 in the X and Y directions via the driving mechanism 18 based on the measurement result of the substrate measurement system 16.

The controller 17 is constituted by a computer (information processing apparatus) including a CPU, a memory, and the like, and comprehensively controls the respective units of the exposure apparatus EXA in accordance with programs stored in a storage or the like. The controller 17 controls exposure processing (exposure method) to project the pattern of the original 1 onto the substrate 3 via the projection optical system 6, and expose the substrate 3, that is, transfer the pattern of the original 1 to the substrate 3. The exposure processing includes alignment processing for the original 1 and the substrate 3, which is a step of aligning the original 1 held by the original stage 2 and the substrate 3 held by the substrate stage 4.

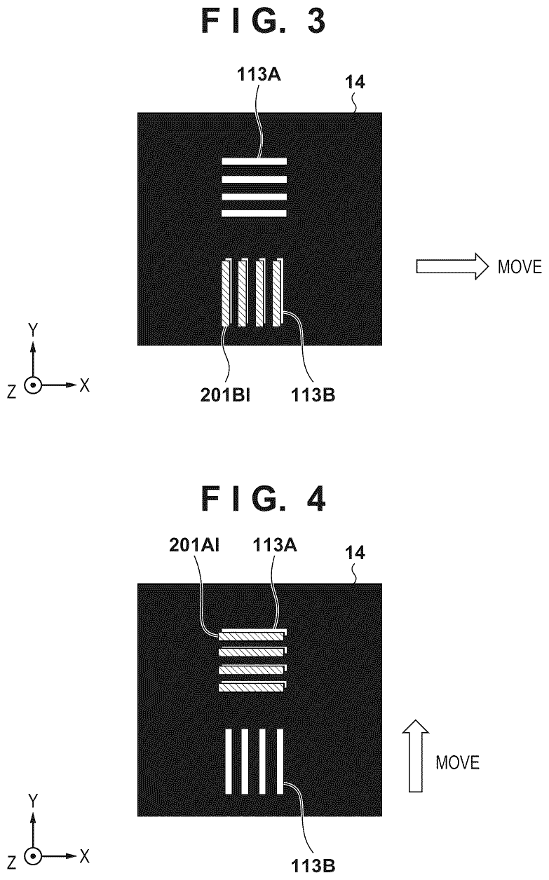

Alignment processing in the exposure apparatus EXA will be explained below. First, alignment processing in a conventional technique will be explained with reference to FIGS. 3 and 4.

FIG. 3 is a view illustrating a state in which light having passed through the reference mark 201 of the original-side reference plate 20 forms an image on the reference mark 113 of the substrate-side reference plate 11 in alignment processing, that is, a state in which the image of the reference mark 201 is formed on the reference mark 113. In FIG. 3, as the second original measurement system 14, the detector of the second original measurement system 14, more specifically, the detection surface of the light amount sensor is represented by a square region, and the third mark 113A and fourth mark 113B of the reference mark 113 are respectively represented by white rectangular regions. In other words, white rectangular regions represent the openings of the third mark 113A and fourth mark 113B, and black regions represent the light-shielding portions of the third mark 113A and fourth mark 113B. As the image of the reference mark 201, a second mark image 201BI of the second mark 201B is represented by a hatched rectangular region.

FIG. 3 illustrates only the second mark image 201BI of the second mark 201B whose longitudinal direction is the Y direction (first direction) perpendicular to the X direction (second direction) because only the second mark 201B out of the reference mark 201 is illuminated. In general, the illumination optical system 5 of the exposure apparatus EXA includes a masking mechanism (not shown) that restricts exposure light and guides it to a specific region of the original 1 or original-side reference plate 20 (that is, illuminates only the specific region). By using the masking mechanism, a state in which only the second mark image 201BI is formed on the reference mark 113 (fourth mark 113B), as illustrated in FIG. 3, can be implemented.

In the state illustrated in FIG. 3, the substrate stage 4 is moved in the X direction indicated by an arrow. In this case, when the second mark image 201BI of the second mark 201B and the light-shielding portion of the fourth mark 113B of the reference mark 113 overlap each other, the amount of light detected by the second original measurement system 14 becomes minimum. In contrast, when the second mark image 201BI and the opening of the fourth mark 113B overlap each other, the amount of light detected by the second original measurement system 14 becomes maximum. This is because light detected by the second original measurement system 14 is light that passes through (the opening of) the second mark 201B and also passes through (the opening of) the fourth mark 113B. In this embodiment, a position of the substrate stage 4 at which the amount of light detected by the second original measurement system 14 becomes maximum is set as a reference in the X direction for the relative positions (relative displacement) of the original stage 2 (original 1) and substrate stage 4 (substrate 3). Note that the maximum amount of the relative displacement in the X direction between the original stage 2 and the substrate stage 4 is much smaller than the product of half the pitch of the periodic alternate arrangement of the openings and light-shielding portions of the original-side second mark 201B and substrate-side fourth mark 113B by the projection magnification of the projection optical system 6.

Similar to FIG. 3, FIG. 4 illustrates a state in which light having passed through the reference mark 201 of the original-side reference plate 20 forms an image on the reference mark 113 of the substrate-side reference plate 11, that is, a state in which the image of the reference mark 201 is formed on the reference mark 113. In FIG. 4, only a first mark image 201AI of the first mark 201A is formed on the reference mark 113 (third mark 113A) by using the masking mechanism.

In the state illustrated in FIG. 4, the substrate stage 4 is moved in the Y direction indicated by an arrow. In this case, when the first mark image 201AI of the first mark 201A and the light-shielding portion of the third mark 113A of the reference mark 113 overlap each other, the amount of light detected by the second original measurement system 14 becomes minimum. In contrast, when the first mark image 201AI and the opening of the third mark 113A overlap each other, the amount of light detected by the second original measurement system 14 becomes maximum. This is because light detected by the second original measurement system 14 is light that passes through (the opening of) the first mark 201A and also passes through (the opening of) the third mark 113A. In this embodiment, a position of the substrate stage 4 at which the amount of light detected by the second original measurement system 14 becomes maximum is set as a reference in the Y direction for the relative positions (relative displacement) of the original stage 2 (original 1) and substrate stage 4 (substrate 3). Note that the maximum amount of the relative displacement in the Y direction between the original stage 2 and the substrate stage 4 is much smaller than the product of half the pitch of the periodic alternate arrangement of the openings and light-shielding portions of the original-side first mark 201A and substrate-side third mark 113A by the projection magnification of the projection optical system 6.

After the relative positions of the original stage 2 and substrate stage 4 in the X and Y directions are obtained in this way, the substrate stage 4 is moved so that the reference mark 201 and the reference mark 113 overlap each other, thereby aligning the original 1 and the substrate 3. In this state, the substrate stage 4 is moved in the Z direction, and when the substrate-side reference plate 11 coincides with the focal plane of the projection optical system 6, the image of the original-side reference mark 201 becomes sharpest. In other words, the blurred portion of the image of the reference mark 201 is not shielded by the light-shielding portion of the substrate-side reference mark 113, but reaches the second original measurement system 14, so the amount of light detected by the second original measurement system 14 is maximized. In this embodiment, a position of the substrate stage 4 at which the amount of light detected by the second original measurement system 14 becomes maximum is set as a reference in the Z direction for the relative positions (relative displacement) of the original stage 2 (original 1) and substrate stage 4 (substrate 3).

FIGS. 3 and 4 illustrate only one second original measurement system 14. However, as described above, a plurality of second original measurement systems 14 may be provided below the substrate-side reference plate 11. For example, the reference marks 201 may be arranged respectively on the left and right of the original-side reference plate 20, and the second original measurement systems 14 may be arranged respectively left and right in correspondence with them. In this case, as described in the conventional technique, the substrate stage 4 is moved once in the X direction, thereby obtaining waveforms representing changes of left and right (two) light amounts, that is, pieces of light amount information. From the pieces of light amount information, an error of the projection magnification of the projection optical system 6 can be obtained. If relative deviations in the Z direction between the original stage 2 and the substrate stage 4 can be obtained for left and right (two) image heights, information about the inclination of the substrate stage 4 with respect to the image plane of the projection optical system 6 can be obtained, and thus the inclination of the substrate stage 4 can be corrected.

In alignment processing according to the conventional technique, two-time movement (stage driving) of the substrate stage 4 in the X and Y directions, and switching of the masking mechanism are necessary in regard to the horizontal direction. In actual exposure processing, only the average value (average focus information) of focus information obtained in regard to the X direction and focus information obtained in regard to the Y direction is sometimes required. Even in such a case, the necessity of two-time stage driving in the Z direction greatly affects the throughput of the exposure apparatus EXA. To further improve the throughput of the exposure apparatus EXA, the efficiency of alignment processing (parallelization of processing) needs to be promoted.

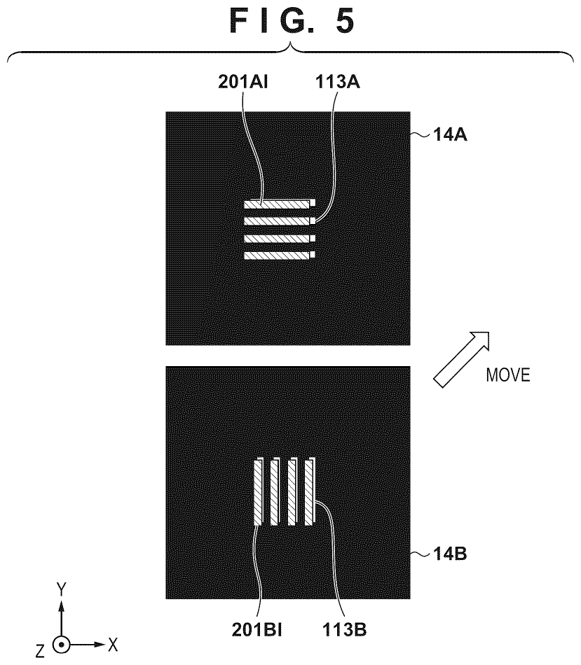

As one method of increasing the efficiency of alignment processing, it is conceivable to move the substrate stage 4 in an oblique direction (third direction) obliquely crossing the Y direction (first direction) and the X direction (second direction) by using two second original measurement systems 14A and 14B, as illustrated in FIG. 5. By one-time stage driving, light amount information about the X direction and light amount information about the Y direction can be simultaneously obtained. Note that the oblique direction in which the substrate stage 4 is moved is, for example, a direction crossing the X and Y directions at an angle of 45° (also called “45° direction” hereinafter). FIG. 5 is a view for explaining alignment processing between the original 1 and the substrate 3 in a comparative example.

In the comparative example illustrated in FIG. 5, the number of second original measurement systems 14, that is, light amount sensors increases, raising the cost and complicating the wiring and the processing system. Further, calibration work is required for an individual difference between the sensitivities or the like of the light amount sensors. The light amount sensor has a minimum package size in addition to the size of the detection surface. When the light amount sensors are arranged without interference between these sizes, an X mark whose longitudinal direction is the X direction, and a Y mark whose longitudinal direction is the Y direction are spaced apart from each other in a reference mark so that they cannot be considered to approximately belong to the same angle of view (image height). Therefore, the comparative example in which the two second original measurement systems 14A and 14B (two light amount sensors) are used as illustrated in FIG. 5 is not practical.

Hence, this embodiment is premised on one second original measurement system 14 (light amount sensor) present for one angle of view, and the masking mechanism is so controlled as to illuminate a reference mark in which X and Y marks are arranged close, that is, illuminate the two marks.

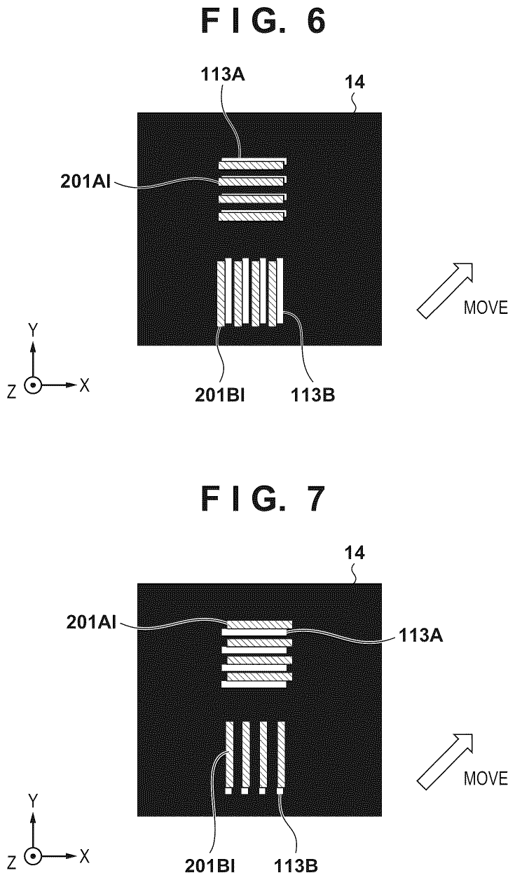

Alignment processing in this embodiment will be explained with reference to FIGS. 6, 7, and 8. More specifically, a position (scanning start position) from which movement of the substrate stage 4 in the oblique direction starts is set in the first state, as illustrated in FIG. 6. The first state is a state in which light (first mark image 201AI) having passed through the opening of the first mark 201A is shielded by the light-shielding portion of the third mark 113A, and light (second mark image 201BI) having passed through the opening of the second mark 201B passes through the opening of the fourth mark 113B.

Here, alignment processing is performed because the relative positions of the original stage 2 (original 1) and substrate stage 4 (substrate 3) are not known. As described above, the ratio between the width of the opening and that of the light-shielding portion in the reference mark 113 is 1:4, and the widths of the opening and light-shielding portion of the reference mark 113 are on the order of 100 nm or more. Considering the overlay accuracy necessary for the exposure apparatus EXA, the measurement accuracy and the correction amount are about several nm at the maximum. In the exposure apparatus EXA, the measurement accuracy of the position of the substrate stage 4 measured by the measurement units 10 and 12 is equal to or smaller than about several nm at the maximum. Hence, the scanning start position of the substrate stage 4 can be set in the first state, as illustrated in FIG. 6.

Note that it is conceivable that the substrate stage 4 expands owing to exposure energy, and the distance between the target 8 to be detected by the measurement units 10 and 12 and the reference mark 113 changes over time from a design value. In such a case, the scanning start position of the substrate stage 4 is corrected by multiplying, by the temperature coefficient of expansion and the distance between the target 8 and the reference mark 113, the result of measuring (variations of) the ambient temperature of the substrate stage 4 by the thermometer 114.

The substrate stage 4 is moved in an oblique direction indicated by an arrow from the first state (scanning start position) illustrated in FIG. 6 along the horizontal surface (surface on which the substrate 3 is held) to the second state, as illustrated in FIG. 7. The second state is a state in which light (first mark image 201AI) having passed through the opening of the first mark 201A passes through the opening of the third mark 113A, and light (second mark image 201BI) having passed through the opening of the second mark 201B is shielded by the light-shielding portion of the fourth mark 113B. In FIG. 7, the numbers of lines (numbers of patterns) of the first mark image 201AI and the light-shielding portions of the third mark 113A are set to be equal to those of lines of the second mark image 201BI and the light-shielding portions of the fourth mark 113B. However, the numbers of lines of the light-shielding portions of the third mark 113A and fourth mark 113B, and lengths in the longitudinal direction can be increased to suppress the influence on the total amount of light detected by the second original measurement system 14 in a period until movement of the substrate stage 4 in the oblique direction ends.

When the substrate stage 4 is further moved in the oblique direction, it returns again to the first state illustrated in FIG. 6. In this embodiment, during stage driving, the substrate stage 4 undergoes a state in which the first amount of light having passed through the first mark 201A and the third mark 113A becomes maximum, and a state in which the second amount of light having passed through the second mark 201B and the fourth mark 113B becomes maximum. Note that the state in which the first light amount becomes maximum is a state in which the second light amount becomes minimum, and the state in which the second light amount becomes maximum is a state in which the first light amount becomes minimum. In the exposure apparatus EXA, the measurement units 10 and 12 measure the position of the substrate stage 4 even during stage driving. By determining positions of the substrate stage 4 at which the first light amount and the second light amount become maximum, relative positions of the original stage 2 (original 1) and substrate stage 4 (substrate 3) in the X and Y directions can be obtained by one-time stage driving. In other words, the relative positions of the first mark 201A and third mark 113A and those of the second mark 201B and fourth mark 113B can be obtained based on pieces of light amount information respectively about the first light amount and second light amount obtained by the second original measurement system 14.

In this embodiment, it is also possible that the reference marks 201 are arranged respectively on the left and right of the original-side reference plate 20, and the second original measurement systems 14 are provided respectively left and right in correspondence with them. In this case, as described above, the substrate stage 4 can be simultaneously moved in the oblique direction for the left and right reference marks 201, thereby obtaining, by one-time stage driving, pieces of light amount information about the X and Y directions respectively by the left and right second original measurement systems 14.

In terms of the measurement accuracy, for example, preprocessing of correcting imaging characteristics such as the magnification and distortion of the projection optical system 6 and the like predicted from information about energy or the like applied in exposure processing is preferably executed before alignment processing. More specifically, the projection optical system 6 is adjusted so that the positional relationship between the first mark 201A and the third mark 113A via the projection optical system 6 and that between the second mark 201B and the fourth mark 113B via the projection optical system 6 satisfy predetermined positional relationships.

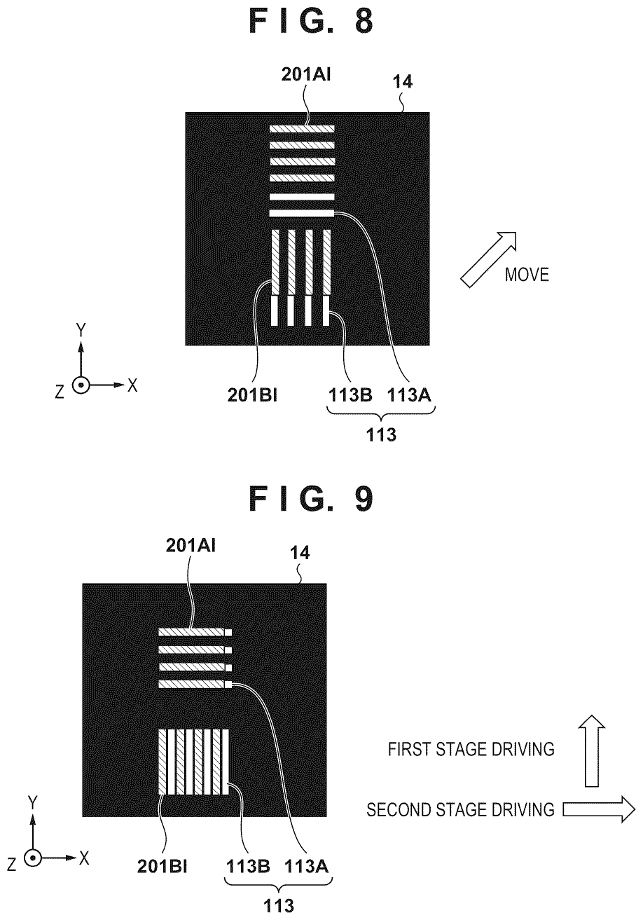

In this embodiment, after the relative positions of the original stage 2 and substrate stage 4 in the X and Y directions are obtained, the original 1 and the substrate 3 can be aligned by moving the substrate stage 4 so that the reference mark 201 and the reference mark 113 overlap each other. In this state, the substrate stage 4 is moved in the Z direction, obtaining average focus information. In this embodiment, therefore, stage driving need not be performed twice in the X and Y directions, and the throughput of the exposure apparatus EXA can be further improved. In some cases, focus information about the X direction and focus information about the Y direction may be individually required. In such a case, the substrate stage 4 is moved in the Z direction in a state in which the first mark image 201AI or the second mark image 201BI is positioned at the light-shielding portion of the reference mark 113. However, the amount of light detected by the second original measurement system 14 (light amount sensor) becomes double the amount of light at the time of measurement in the X and Y directions. Thus, the substrate stage 4 may be moved so that half the first mark image 201AI or second mark image 201BI is positioned at the opening of the reference mark 113, as illustrated in FIG. 8.

In this fashion, according to this embodiment, the substrate stage 4 is moved in the oblique direction in alignment processing so as to include the state in which the first mark image 201AI overlaps the third mark 113A, and the state in which the second mark image 201BI overlaps the fourth mark 113B. The second original measurement system 14 can obtain light amount information about the first amount of light having passed through the first mark 201A and the third mark 113A, and light amount information about the second amount of light having passed through the second mark 201B and the fourth mark 113B. Based on the pieces of light amount information, the relative positions of the first mark 201A and third mark 113A and those of the second mark 201B and fourth mark 113B can be obtained. According to this embodiment, while shortening the time taken for alignment processing (stage driving), the original 1 and the substrate 3 can be aligned at high accuracy, which contributes to the improvement of the overlay accuracy and throughput in the exposure apparatus EXA.

In this embodiment, the scanning start position from which movement of the substrate stage 4 in the oblique direction starts is set in the first state in alignment processing, but is not limited to this. For example, the scanning start position of the substrate stage 4 may be set in the second state, and the substrate stage 4 may be moved in the oblique direction to reach the first state. In this way, the scanning start position of the substrate stage 4 is not limited, and the substrate stage 4 suffices to be moved in the oblique direction so as to include the first and second states in alignment processing. An example of stage driving of moving the substrate stage 4 in the oblique direction is stage driving of starting movement of the substrate stage 4 in the oblique direction from the first state and ending the movement of the substrate stage 4 in the oblique direction in the second state.

Stage driving illustrated in FIG. 9 is conceivable as another form of stage driving premised on one second original measurement system 14 (light amount sensor) present for one angle of view. As illustrated in FIG. 9, this stage driving includes the first stage driving of moving the substrate stage 4 in the Y direction from the first state (FIG. 6), and the second stage driving of moving the substrate stage 4 in the X direction in a state after the end of the first stage driving. Such stage driving is stage driving including braking in which it is necessary to accelerate the substrate stage 4 in the X direction, after reaching a predetermined speed, decelerate it, then accelerate it in the Y direction, after reaching a predetermined speed, decelerate it. This substantially equals performing two-time stage driving. Note that even if the substrate stage 4 is continuously moved so as to draw a circular orbit while maintaining a predetermined speed, the speed in the Y direction needs to be increased while decreasing the speed in the X direction. Hence, light amount information obtained by the second original measurement system 14 cannot be sampled at equal intervals, and the light amount information becomes sparse or dense. This undesirably complicates both stage driving and light amount information. FIG. 9 is a view for explaining alignment processing between the original 1 and the substrate 3 as a comparative example.

A technique for stabilizing alignment processing in this embodiment will be explained. This technique is mainly for ensuring high reliability of measurement required for alignment processing in the exposure apparatus EXA.

For example, in alignment processing, stage driving of moving the substrate stage 4 in the oblique direction is not limited to be performed once, but may be performed a plurality of times, as described above. Performing stage driving a plurality of times can average variations of the range of measurement reproducibility that are inevitable in measurement in alignment processing.

In this embodiment, as an example of stage driving, the first or second state is preferably implemented at high accuracy at the scanning start position of the substrate stage 4 for the following two reasons.

First, if the scanning start position of the substrate stage 4 greatly deviates, both light having passed through the first mark 201A and the third mark 113A, and light having passed through the second mark 201B and the fourth mark 113B reach the second original measurement system 14. When light amount information obtained by the second original measurement system 14 is a waveform representing the light amount, waveforms corresponding to the respective light beams are mixed, making it difficult to separate position information in the X direction and that in the Y direction.

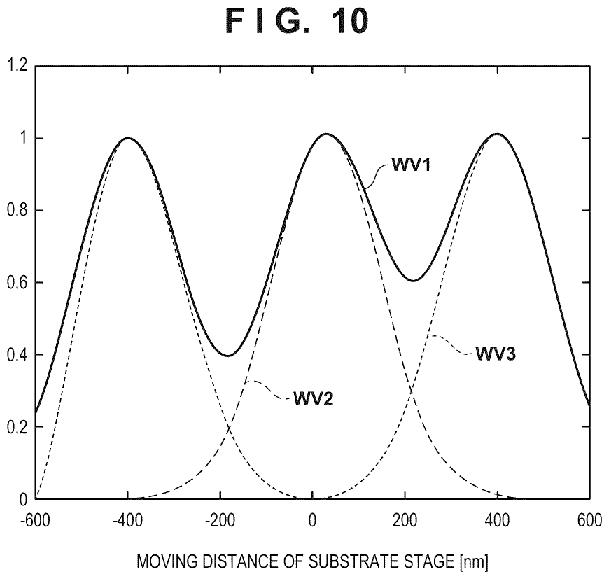

The second reason is to suppress the shift amount of the peak of the light amount by the waveform proximity effect. FIG. 10 is a graph illustrating an example of waveforms each obtained as light amount information by the second original measurement system 14, and representing the amount of light detected by the second original measurement system 14. FIG. 10 illustrates a composite waveform WV1 that is a waveform obtained by moving the substrate stage 4 in the oblique direction. FIG. 10 also illustrates an X waveform WV2 that is a waveform obtained by moving the substrate stage 4 in the X direction, and a Y waveform WV3 that is a waveform obtained by moving the substrate stage 4 in the Y direction. The composite waveform WV1 is a waveform obtained by compositing the X waveform WV2 and the Y waveform WV3, and represents the relative positions of the original stage 2 (original 1) and substrate stage 4 (substrate 3) in the X and Y directions. The barycenter of the waveform of a portion of the composite waveform WV1 that corresponds to the X waveform WV2 apparently shifts rightward owing to the waveform proximity effect. When the X waveform WV2 and the Y waveform WV3 are added, the peak of the portion corresponding to the X waveform WV2 also shifts rightward in numerical calculation and theoretically though it is difficult to read this from FIG. 10. This shift is caused by a large deviation of the scanning start position of the substrate stage 4. If the X waveform WV2 is positioned at the center of a portion of the composite waveform WV1 that corresponds to the Y waveform WV3, the left-right symmetry of the composite waveform WV1 is rarely unbalanced, and the peak position hardly shifts. Note that the unbalance of the left-right symmetry caused by a shift of about several nm of a measurement target can be ignored. From these viewpoints, it is very effective to determine (correct) the scanning start position of the substrate stage 4 based on the measurement result of the thermometer 114, as described above.

The composite waveform WV1 can also be divided into the X waveform WV2 and the Y waveform WV3 by calculation processing. For example, as described with reference to FIG. 9, stage driving including the first stage driving and the second stage driving is executed in advance, obtaining and storing a function f(x) representing the X waveform and a function g(x) representing the Y waveform, where x is a variable representing the moving distance (position) of the substrate stage 4. Note that the functions f(x) and g(x) may be logically calculated by optical simulation using design values. If each of the functions f(x) and g(x) is a unimodal function having peaks at positions a and b, a and b can be obtained by fitting in the sum of the functions f(x) and g(x), as given by equation (1):

composite waveform (x)=f(x−a)+g(x−b) (1)

If the x symmetry of the functions f(x) and g(x) is assumed, an odd-order component containing a linear component upon fitting the composite waveform (x) in a polynomial expression may be regarded as an error caused by the waveform proximity effect, and a peak may be obtained by removing the odd-order component. For example, letting T(x) be the vicinity of a peak in the information obtaining direction extracted from the composite waveform (x), the peak may be obtained by fitting T(x) in a finite-dimensional polynomial expression as given by equation (2), and removing the odd-order component:

T(x)=a(x−x0)4+b(x−x0)3+c(x−x0)2+d(x−x0)+e (2)

In this manner, the relative positions of the original stage 2 (original 1) and substrate stage 4 (substrate 3) may be obtained based on a waveform obtained by removing an asymmetrical component from the composite waveform WV1, or a waveform obtained by fitting in the sum of a function representing the X waveform and a function representing the Y waveform.

An article manufacturing method according to an embodiment of the present disclosure is, for example, suitable to manufacture an article such as a semiconductor device, a liquid crystal display device, a flat panel display, or a MEMS. The manufacturing method includes a step of exposing a substrate applied with a photosensitive material by using the above-described exposure apparatus EXA (exposure processing), and a step of developing the exposed photosensitive material. In addition, an etching step, an ion implantation step, or the like is performed on the substrate using the pattern of the developed photosensitive material as a mask to form a circuit pattern on the substrate. By repeating the steps of exposure, developing, etching, and the like, a circuit pattern formed by a plurality of layers is formed on the substrate. In a post-process, dicing (processing) is performed on the substrate bearing the circuit pattern, and chip mounting, bonding, and inspection steps are performed. The manufacturing method can also include other known steps (oxidation, deposition, vapor deposition, doping, planarization, resist removal, and the like). The article manufacturing method according to this embodiment is superior to a conventional method in at least one of the performance, quality, productivity, and production cost of the article.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent application No. 2025-004945 filed on Jan. 14, 2025, which is hereby incorporated by reference herein in its entirety.

What is claimed is:

1. An exposure apparatus that projects a pattern of an original onto a substrate via a projection optical system, and exposes the substrate, the apparatus comprising:
a first mark having a longitudinal direction in a first direction, and a second mark having a longitudinal direction in a second direction different from the first direction, the first mark and the second mark being arranged on a surface on which the original is arranged;
a third mark having a longitudinal direction in the first direction, and a fourth mark having a longitudinal direction in the second direction, the third mark and the fourth mark being arranged on a substrate stage configured to hold the substrate;
a detector configured to detect a first light amount of light having passed through the first mark and the third mark, and a second light amount of light having passed through the second mark and the fourth mark, thereby obtaining light amount information; and
a controller configured to obtain pieces of light amount information respectively about the first light amount and the second light amount by the detector by moving, in a third direction obliquely crossing the first direction and the second direction, the substrate stage along a surface holding the substrate to include a state in which an image of the first mark overlaps the third mark, and a state in which an image of the second mark overlaps the fourth mark, and obtain, based on the pieces of light amount information, relative positions of the first mark and the third mark, and relative positions of the second mark and the fourth mark.

2. The apparatus according to claim 1, wherein the first mark and the third mark have a configuration in which openings and light-shielding portions are periodically arrayed in the second direction,
the second mark and the fourth mark have a configuration in which openings and light-shielding portions are periodically arrayed in the first direction, and
the controller moves the substrate stage in the third direction along the surface holding the substrate to include a first state in which light having passed through the opening of the first mark is shielded by the light-shielding portion of the third mark, and light having passed through the opening of the second mark passes through the opening of the fourth mark.

3. The apparatus according to claim 2, wherein the controller moves the substrate stage in the third direction along the surface holding the substrate to include a second state in which light having passed through the opening of the first mark passes through the opening of the third mark, and light having passed through the opening of the second mark is shielded by the light-shielding portion of the fourth mark.

4. The apparatus according to claim 3, wherein the controller starts movement of the substrate stage in the third direction from the first state, and ends the movement of the substrate stage in the third direction in the second state.

5. The apparatus according to claim 1, wherein the controller moves the substrate stage in the third direction along the surface holding the substrate to include a state in which the first light amount becomes maximum and the second light amount becomes minimum, and a state in which the first light amount becomes minimum and the second light amount becomes maximum.

6. The apparatus according to claim 1, wherein the projection optical system i adjusted to set a positional relationship between the first mark and the third mark via the projection optical system and a positional relationship between the second mark and the fourth mark to satisfy a predetermined positional relationship.

7. The apparatus according to claim 1, further comprising a measurement unit configured to measure a position of the substrate stage,
wherein the controller controls movement of the substrate stage in the third direction based on a measurement result of the measurement unit.

8. The apparatus according to claim 7, further comprising a thermometer configured to measure an ambient temperature of the substrate stage,
wherein the controller corrects, based on a measurement result of the thermometer, a position of the substrate stage from which the movement of the substrate stage in the third direction starts.

9. The apparatus according to claim 1, wherein the detector obtains, as the light amount information, a composite waveform obtained by compositing a waveform representing the first light amount and a waveform representing the second light amount, and
the controller obtains, based on a waveform obtained by removing an asymmetry component from the composite waveform, the relative positions of the first mark and the third mark and the relative positions of the second mark and the fourth mark.

10. The apparatus according to claim 1, wherein the detector obtains, as the light amount information, a composite waveform obtained by compositing a first waveform representing the first light amount and a second waveform representing the second light amount, and
the controller obtains, based on a waveform obtained by fitting the composite waveform in a sum of a function representing the first waveform and a function representing the second waveform, the relative positions of the first mark and the third mark and the relative positions of the second mark and the fourth mark.

11. The apparatus according to claim 1, wherein the detector includes one light amount sensor configured to detect the first light amount and the second light amount.

12. The apparatus according to claim 1, wherein the detector includes a light amount sensor configured to detect the first light amount, and a light amount sensor configured to detect the second light amount.

13. An exposure method of projecting a pattern of an original onto a substrate via a projection optical system, and exposing the substrate, the method comprising:
obtaining light amount information by detecting a first light amount of light having passed through a first mark that is arranged on a surface on which the original is arranged and that has a longitudinal direction in a first direction, and a third mark that is arranged on a substrate stage configured to hold the substrate and has a longitudinal direction in the first direction, and a second light amount of light having passed through a second mark that is arranged on the surface and has a longitudinal direction in a second direction different from the first direction, and a fourth mark that is arranged on the substrate stage and has a longitudinal direction in the second direction; and
obtaining relative positions of the first mark and the third mark and relative positions of the second mark and the fourth mark based on the light amount information,
wherein in the obtaining the light amount information, pieces of light amount information respectively about the first light amount and the second light amount are obtained by moving, in a third direction obliquely crossing the first direction and the second direction, the substrate stage along a surface holding the substrate to include a state in which an image of the first mark overlaps the third mark, and a state in which an image of the second mark overlaps the fourth mark.

14. An article manufacturing method comprising:
exposing a substrate using an exposure apparatus defined in claim 1;
developing the substrate exposed; and
manufacturing an article from the substrate developed.
